(19) United States
(12) Patent Application Publication
(10) Pub. No.: US 2025/0080078 A1
(43) Pub. Date: Mar. 6, 2025

(54) ACOUSTIC WAVE DEVICE

(71) Applicant: Murata Manufacturing Co., Ltd., Nagaokakyo-shi (JP)

(72) Inventor: Kazunori INOUE, Nagaokakyo-shi (JP)

(21) Appl. No.: 18/950,503

(22) Filed: Nov. 18, 2024

Related U.S. Application Data
(63) Continuation of application No. PCT/JP2023/018453, filed on May 17, 2023.
(60) Provisional application No. 63/343,654, filed on May 19, 2022.

(51) Int. Cl. H03H 9/02; H03H 3/02; H03H 9/13; H03H 9/17

(52) U.S. Cl. CPC H03H 9/02133; H03H 3/02; H03H 9/02031; H03H 9/02102; H03H 9/02157; H03H 9/02228; H03H 9/132; H03H 9/173; H03H 9/176; H03H 2003/021

(57) ABSTRACT

An acoustic wave device includes a support, a piezoelectric layer including first and second main surfaces, and an IDT electrode including first and second busbar portions, and first and second electrode fingers connected to the first and second busbar portions and being interdigitated with each other. A region in which first and second electrode fingers adjacent to each other overlap each other is an intersection region. A cavity portion is provided in the support and overlaps the intersection region. At least one of the first and second busbar portions includes an outer busbar not overlapping the cavity portion, and at least one of protruding electrodes extending from the outer busbar toward the intersection region. The at least one protruding electrode overlaps an outer peripheral edge of the cavity portion.

### CROSS REFERENCE TO RELATED APPLICATIONS

This application claims the benefit of priority to Provisional Application No. 63/343,654 filed on May 19, 2022 and is a Continuation Application of PCT Application No. PCT/JP2023/018453 filed on May 17, 2023. The entire contents of each application are hereby incorporated herein by reference.

### BACKGROUND OF THE INVENTION

### 1. Field of the Invention

The present invention relates to acoustic wave devices.

### 2. Description of the Related Art

In the related art, acoustic wave devices have been widely used in, for example, filters for cellular phones. In recent years, an acoustic wave device in which a bulk wave in a thickness-shear mode is used has been proposed as described in U.S. Pat. No. 10,491,192. In this acoustic wave device, a piezoelectric layer is provided on a support body. An interdigital transducer (IDT) electrode is provided on the piezoelectric layer. The IDT electrode has a pair of comb-shaped electrodes. Each of the comb-shaped electrodes has a busbar and a plurality of electrode fingers. The pair of comb-shaped electrodes are interdigitated with each other on the piezoelectric layer. The pair of comb-shaped electrodes are connected to respective potentials different from each other. By applying an AC voltage to the IDT electrode, a bulk wave in a thickness-shear mode is excited.

In the acoustic wave device described in U.S. Pat. No. 10,491,192, the support body is provided with a through-hole. The piezoelectric layer is provided on the support body so as to cover the through-hole. Thus, in a laminate of the piezoelectric layer and the support body, a portion of the piezoelectric layer covering the through-hole is in a form of a membrane.

In the membrane portion, a region where electrode fingers adjacent to each other face each other is located. When the region is referred to as an intersection region, stress is likely to concentrate between the intersection region and the busbar. Thus, when a crack occurs in the membrane portion, the crack may extend between the intersection region and the busbar. Accordingly, the electrode finger of the IDT electrode is easily broken. When the number of broken electrode fingers increases, electrostatic capacity may be generated in series with the IDT electrode. This may cause a change in filter characteristics.

### SUMMARY OF THE INVENTION

Example embodiments of the present invention provide acoustic wave devices in each of which an extension of a crack is reduced or prevented.

An acoustic wave device according to an example embodiment of the present invention includes a support including a support substrate, a piezoelectric layer on the support and including a first main surface and a second main surface facing each other, and an IDT electrode on at least one of the first main surface and the second main surface of the piezoelectric layer, wherein the IDT electrode includes a first busbar portion and a second busbar portion facing each other, and a plurality of electrode fingers including one or more first electrode fingers including one ends connected to the first busbar portion and one or more second electrode fingers including one ends connected to the second busbar portion, the first electrode fingers and the second electrode fingers are interdigitated with each other, a region where the first electrode fingers and the second electrode fingers adjacent to each other overlap each other when viewed from a direction orthogonal or substantially orthogonal to a direction in which the first electrode fingers and the second electrode fingers extend is an intersection region, the support includes a cavity portion, the cavity portion overlaps the intersection region in plan view, at least one of the first busbar portion and the second busbar portion includes an outer busbar not overlapping the cavity portion in plan view, and one or more protruding electrodes extending from the outer busbar toward the intersection region and facing an electrode finger of the plurality of electrode fingers that is not connected to the outer busbar, and the protruding electrodes overlap an outer peripheral edge of the cavity portion in plan view.

According to example embodiments of the present invention, acoustic wave devices in each of which an extension of a crack is reduced or prevented are provided.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view of an acoustic wave device according to a first example embodiment of the present invention.

FIG. 2 is a schematic cross-sectional view taken along a line I-I in FIG. 1.

FIG. 3 is a schematic plan view of an acoustic wave device of a comparative example.

FIG. 4 is a schematic plan view illustrating a portion of the acoustic wave device of the comparative example in an enlarged manner, and is a diagram illustrating that a broken portion is equivalent to a capacitance portion.

FIG. 5 is a schematic cross-sectional view of an acoustic wave device according to a second example embodiment of the present invention, taken along an electrode finger extending direction.

FIGS. 6A to 6C are schematic cross-sectional views illustrating a portion corresponding to the cross-section illustrated in FIG. 5, for explaining a sacrificial layer forming step and an insulating layer forming step in an example of a method for manufacturing the acoustic wave device according to the second example embodiment of the present invention.

FIGS. 7A to 7D are schematic cross-sectional views illustrating a portion corresponding to the cross-section illustrated in FIG. 5, for explaining a support substrate bonding step, a piezoelectric layer grinding step, an IDT electrode forming step and a wiring electrode forming step in the example of the method for manufacturing the acoustic wave device according to the second example embodiment of the present invention.

FIGS. 8A and 8B are schematic elevational cross-sectional views for explaining a through-hole forming step and a sacrificial layer removing step in the example of the method for manufacturing the acoustic wave device according to the second example embodiment of the present invention.

FIG. 9A is a schematic perspective view illustrating an appearance of an acoustic wave device in which a bulk wave in a thickness-shear mode is used, and FIG. 9B is a plan view illustrating an electrode structure on a piezoelectric layer.

FIG. 10 is a cross-sectional view of a portion taken along a line A-A in FIG. 9A.

FIG. 11A is a schematic elevational cross-sectional view for explaining a Lamb wave propagating through a piezoelectric film of an acoustic wave device, and FIG. 11B is a schematic elevational cross-sectional view for explaining a bulk wave in a thickness-shear mode propagating through the piezoelectric film in the acoustic wave device.

FIG. 12 is a diagram illustrating an amplitude direction of the bulk wave in the thickness-shear mode.

FIG. 13 is a graph showing resonance characteristics of an acoustic wave device in which the bulk wave in the thickness-shear mode is used.

FIG. 14 is a graph showing a relationship between d/p and fractional bandwidth as a resonator, where p is a center-to-center distance between adjacent electrodes and d is a thickness of a piezoelectric layer.

FIG. 15 is a plan view of an acoustic wave device in which the bulk wave in the thickness-shear mode is used.

FIG. 16 is a graph showing resonance characteristics of an acoustic wave device of a reference example in which a spurious mode appears.

FIG. 17 is a graph showing a relationship between fractional bandwidth and phase rotation amount of impedance of a spurious mode normalized by about 180 degrees as magnitude of the spurious mode.

FIG. 18 is a graph showing a relationship between d/2p and metallization ratio MR.

FIG. 19 is a graph showing a map of fractional bandwidth with respect to Euler angles (0°, θ, ψ) of LiNbO₃ when d/p approaches 0 without limit.

FIG. 20 is a partially cutaway perspective view for explaining an acoustic wave device in which a Lamb wave is used.

### DETAILED DESCRIPTION OF THE EXAMPLE EMBODIMENTS

Hereinafter, the present invention will be clarified by explaining specific example embodiments of the present invention with reference to the drawings.

The example embodiments described in the present specification are merely examples, and partial replacement or combination of configurations is possible between different example embodiments.

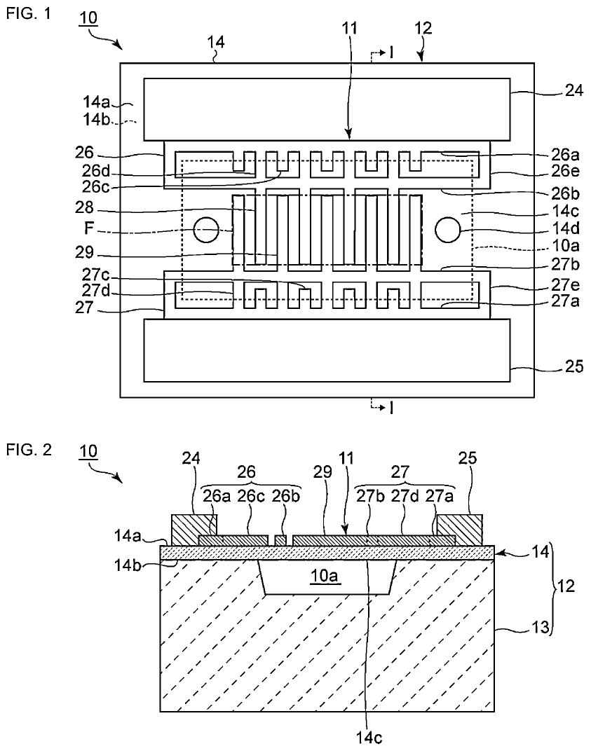

FIG. 1 is a schematic plan view of an acoustic wave device according to a first example embodiment of the present invention. FIG. 2 is a schematic cross-sectional view taken along the line I-I in FIG. 1.

As illustrated in FIG. 1, an acoustic wave device 10 includes a piezoelectric substrate 12 and an IDT electrode 11. The piezoelectric substrate 12 is a substrate having piezoelectricity. As illustrated in FIG. 2, the piezoelectric substrate 12 includes a support 13 and a piezoelectric layer 14. In the present example embodiment, the support 13 includes only a support substrate. However, the support 13 may be a laminate including the support substrate.

The piezoelectric layer 14 includes a first main surface 14a and a second main surface 14b. The first main surface 14a and the second main surface 14b face each other. Of the first main surface 14a and the second main surface 14b, the second main surface 14b is located closer to the support 13.

As a material of the support substrate as the support 13, for example, a semiconductor such as silicon, ceramics such as aluminum oxide, or the like can be used. The piezoelectric layer 14 is, for example, a lithium niobate layer such as a LiNbO₃ layer or a lithium tantalate layer such as a LiTaO₃ layer.

As illustrated in FIG. 2, the support 13 is provided with a concave portion. The piezoelectric layer 14 is provided on the support 13 so as to close the concave portion. Thus, a hollow portion is formed. This hollow portion is a cavity portion 10a. In the present example embodiment, the support 13 and the piezoelectric layer 14 are disposed such that a part of the support 13 and a part of the piezoelectric layer 14 face each other with the cavity portion 10a interposed therebetween. However, the concave portion may be provided in the piezoelectric layer 14. Note that the cavity portion 10a may be a through-hole provided in the support 13.

The piezoelectric layer 14 includes a membrane portion 14c. To be specific, the membrane portion 14c is a portion of the piezoelectric layer 14 that overlaps the cavity portion 10a in plan view. In the present specification, “in plan view” refers to a view along a laminate direction of the support 13 and the piezoelectric layer 14 from a direction corresponding to an upper side in FIG. 2. In FIG. 2, for example, of the support 13 and the piezoelectric layer 14, the piezoelectric layer 14 side is on the upper side.

The first main surface 14a of the piezoelectric layer 14 includes the IDT electrode 11. As illustrated in FIG. 1, the IDT electrode 11 includes a pair of busbar portions and a plurality of electrode fingers. The pair of busbar portions are specifically a first busbar portion 26 and a second busbar portion 27. The first busbar portion 26 and the second busbar portion 27 face each other. The plurality of electrode fingers are specifically a plurality of first electrode fingers 28 and a plurality of second electrode fingers 29. Each of one ends of the plurality of first electrode fingers 28 is connected to the first busbar portion 26. Each of one ends of the plurality of second electrode fingers 29 is connected to the second busbar portion 27. The plurality of first electrode fingers 28 and the plurality of second electrode fingers 29 are interdigitated with each other. The IDT electrode 11 include a single-layer metal film or a laminated metal film.

Hereinafter, a direction in which the plurality of first electrode fingers 28 and the plurality of second electrode fingers 29 extend is referred to as an electrode finger extending direction, and a direction orthogonal or substantially orthogonal to the electrode finger extending direction is referred to as an electrode finger orthogonal direction. The electrode finger orthogonal direction is parallel or substantially parallel to a direction in which the first electrode finger 28 and the second electrode finger 29 adjacent to each other face each other. When the IDT electrode 11 is viewed from the electrode finger orthogonal direction, a region where the first electrode finger 28 and the second electrode finger 29 adjacent to each other overlap each other is an intersection region F. The intersection region F overlaps the cavity portion 10a in plan view.

As illustrated in FIG. 1 and FIG. 2, the first busbar portion 26 includes an outer busbar 26a, an inner busbar 26b and a plurality of protruding electrodes 26c. In FIG. 2, a boundary between portions of the IDT electrode 11 is indicated by a broken line. Of the outer busbar 26a and the inner busbar 26b, the inner busbar 26b is located inside in the electrode finger extending direction. To be more specific, as illustrated in FIG. 1, of the outer busbar 26a and the inner busbar 26b, the inner busbar 26b is located closer to the intersection region F. One ends of the plurality of first electrode fingers 28 are connected to the inner busbar 26b of the first busbar portion 26.

The outer busbar 26a does not overlap the cavity portion 10a in plan view. On the other hand, the inner busbar 26b partially overlaps the cavity portion 10a in plan view. In particular, the inner busbar 26b overlaps the cavity portion 10a in plan view except for a vicinity of each of end portions in the electrode finger orthogonal direction. In other words, the inner busbar 26b extends to portions that do not overlap the cavity portion 10a in plan view.

The plurality of protruding electrodes 26c extend from the outer busbar 26a toward the intersection region F and face the intersection region F. The plurality of protruding electrodes 26c overlap an outer peripheral edge of the cavity portion 10a in plan view. To be specific, the plurality of protruding electrodes 26c extends from portions that do not overlap the cavity portion 10a so as to extend to portions overlapping the cavity portion 10a in plan view. The inner busbar 26b is located between the plurality of protruding electrodes 26c and the intersection region F. The plurality of protruding electrodes 26c is not in contact with the inner busbar 26b. The plurality of protruding electrodes 26c face the plurality of second electrode fingers 29 with the inner busbar 26b interposed therebetween.

The first busbar portion 26 includes a plurality of first connecting portions 26d and a plurality of second connecting portions 26e. The first connecting portion 26d is a connecting portion. The plurality of first connecting portions 26d and the plurality of second connecting portions 26e connect the inner busbar 26b and the outer busbar 26a.

The plurality of first connecting portions 26d are disposed on extension lines of the plurality of first electrode fingers 28 connected to the inner busbar 26b. This configuration is equivalent to a configuration in which the first finger electrode finger 28 includes the first connecting portion 26d. When the first electrode finger 28 includes the first connecting portion 26d, the first electrode finger 28 is connected to the outer busbar 26a at the first connecting portion 26d. On the other hand, the plurality of second connecting portions 26e is not located on the extension lines of the plurality of first electrode fingers 28. The plurality of second connecting portions 26e is located at a portion not overlapping the cavity portion 10a in plan view. The second connecting portion 26e is a portion included in the outer busbar 26a.

To be more specific, in the present example embodiment, the first busbar portion 26 includes two second connecting portions 26e. The two second connecting portions 26e connect both end portions of the inner busbar 26b in the electrode finger orthogonal direction to the outer busbar 26a. Thus, the first busbar portion 26 has a configuration in which the plurality of first connecting portions 26d and the plurality of protruding electrodes 26c are provided in a void portion surrounded by the outer busbar 26a, the inner busbar 26b and the two second connecting portions 26e.

Similarly, the second busbar portion 27 also includes an outer busbar 27a, an inner busbar 27b, a plurality of protruding electrodes 27c, a plurality of first connecting portions 27d and a plurality of second connecting portions 27e. The second connecting portion 27e is, specifically, a portion included in the outer busbar 27a. The second busbar portion 27 has a configuration in which the plurality of first connecting portions 27d and the plurality of protruding electrodes 27c are provided in a void portion surrounded by the outer busbar 27a, the inner busbar 27b and two second connecting portions 27e. One ends of the plurality of second electrode fingers 29 are connected to the inner busbar 27b. The plurality of protruding electrodes 27c faces the plurality of first electrode fingers 28 with the inner busbar 27b interposed therebetween.

The configuration of the second busbar portion 27 and the second electrode finger 29 is equivalent to a configuration in which the second electrode finger 29 includes the first connecting portion 27d. When the second electrode finger 29 includes the first connecting portion 27d, the second electrode finger 29 is connected to the outer busbar 27a at the first connecting portion 27d.

It is sufficient that at least one of the first busbar portion 26 and the second busbar portion 27 includes at least one protruding electrode. For example, one of the first busbar portion 26 and the second busbar portion 27 may have a bar shape without the outer busbar and the inner busbar. However, it is preferable that at least one of the first busbar portion 26 and the second busbar portion 27 includes a plurality of protruding electrodes. It is more preferable that both of the first busbar portion 26 and the second busbar portion 27 include pluralities of protruding electrodes.

In the present example embodiment, the first busbar portion 26 includes the plurality of protruding electrodes 26c, and the plurality of protruding electrodes 26c overlaps the outer peripheral edge of the cavity portion 10a in plan view. This makes it possible to move a portion where stress is concentrated from a region between the intersection region F and the first busbar portion 26 toward a center of the membrane portion 14c, and to reduce the stress itself. In addition, the first busbar portion 26 includes the plurality of protruding electrodes 26c, and thus it is possible to disperse the stress. Thus, extension of a crack along the first busbar portion 26 can be reduced or prevented. Thus, breakage of the first electrode finger 28 can be reduced or prevented, and deterioration in electrical characteristics of the acoustic wave device 10 can be reduced or prevented.

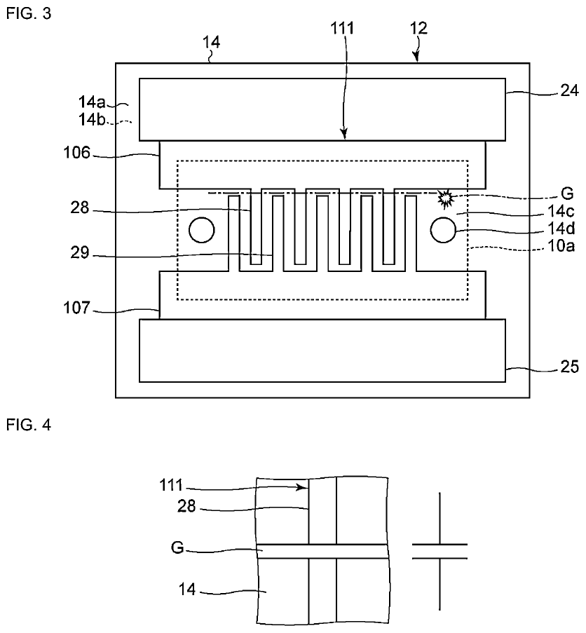

The above advantageous effects of the first example embodiment will be described in more detail with reference to a comparative example. In the comparative example illustrated in FIG. 3, a first busbar portion 106 and a second busbar portion 107 each include a bar shape without an outer busbar and an inner busbar. In the comparative example, a crack G is generated in the membrane portion 14c of the piezoelectric layer 14. The crack G is generated in a vicinity of the first busbar portion 106. As described above, stress is likely to concentrate between an intersection region and the first busbar portion 106. Thus, the crack G extends along the first busbar portion 106. Thus, the plurality of first electrode fingers 28 is broken.

As illustrated in FIG. 4 in an enlarged manner, when the first electrode finger 28 is broken, a portion where electrodes face each other is generated. This portion is equivalent to a capacitance portion connected in series to an IDT electrode 111, as schematically illustrated in FIG. 4. Thus, electrical characteristics of the acoustic wave device may be deteriorated.

On the other hand, in the first example embodiment illustrated in FIG. 1, the first busbar portion 26 includes the plurality of protruding electrodes 26c. Accordingly, as described above, breakage of the first electrode finger 28 can be reduced or prevented, and deterioration in the electrical characteristics of the acoustic wave device 10 can be reduced or prevented. In addition, the second busbar portion 27 also includes the plurality of protruding electrodes 27c. Thus, breakage of the second electrode finger 29 can also be reduced or prevented. Thus, deterioration in the electrical characteristics of the acoustic wave device 10 can be more reliably reduced or prevented.

In the following, further details of the configuration of the first example embodiment will be described.

The acoustic wave device 10 according to the first example embodiment is an acoustic wave resonator configured such that a bulk wave in a thickness-shear mode can be used. More specifically, in the acoustic wave device 10, for example, d/p is equal to or less than about 0.5, where d is a thickness of the piezoelectric layer 14 and p is a center-to-center distance between the electrode fingers adjacent to each other. Accordingly, the bulk wave in the thickness-shear mode is suitably excited.

When the IDT electrode 11 is viewed from the electrode finger orthogonal direction, a region that is a region where the electrode fingers adjacent to each other overlap each other and is a region between centers of the adjacent electrode fingers is an excitation region. That is, in the first example embodiment, the intersection region F includes a plurality of the excitation regions. The intersection region F and each excitation region are regions of the piezoelectric layer 14 defined based on the configuration of the IDT electrode 11. In each excitation region, the bulk wave in the thickness-shear mode is excited.

On the other hand, the acoustic wave device 10 may be configured such that a plate wave can be used. In this case, the excitation region is the intersection region F.

The cavity portion 10a illustrated in FIG. 2 is an acoustic reflector. The acoustic reflector can effectively confine energy of an acoustic wave to a side of the piezoelectric layer 14.

A wiring electrode 24 is connected to the first busbar portion 26. To be more specific, the wiring electrode 24 is provided on top of the outer busbar 26a of the first busbar portion 26 and the piezoelectric layer 14. The wiring electrode 24 does not extend to a boundary between the outer busbar 26a and the plurality of protruding electrodes 26c. A thickness of the wiring electrode 24 is larger than a thickness of the first busbar portion 26. This makes it easy to reduce electrical resistance of the wiring electrode 24.

Similarly, a wiring electrode 25 is connected to the second busbar portion 27. The acoustic wave device 10 can be used in, for example, a filter device. In this case, the IDT electrode 11 is connected to, for example, another element in the filter device or a ground potential via the wiring electrode 24 and the wiring electrode 25.

Returning to FIG. 1, the piezoelectric layer 14 is provided with a plurality of through-holes 14d. The plurality of through-holes 14d are used when the cavity portion 10a is provided. In particular, when the acoustic wave device 10 is manufactured, the cavity portion 10a is formed by removing a sacrificial layer by, for example, etching. At this time, the sacrificial layer is removed using the through-hole 14d.

The number of locations where the through-holes 14d are provided in the piezoelectric layer 14 is not particularly limited. Depending on a method for manufacturing the acoustic wave device 10, at least one through-hole 14d may be provided in the piezoelectric layer 14. Alternatively, the piezoelectric layer 14 is not necessarily be provided with the through-hole 14d.

Incidentally, the first busbar portion 26 does not necessarily include the second connecting portion 26e. Even in this case, the outer busbar 26a and the inner busbar 26b can be suitably connected to each other by the plurality of first connecting portions 26d. This makes it possible to suitably reduce electrical resistance of the first busbar portion 26.

However, the first busbar portion 26 preferably includes at least one second connecting portion 26e. Thus, a configuration can be obtained in which the outer busbar 26a and the inner busbar 26b are connected to each other at a portion supported by the support 13 illustrated in FIG. 2. This can increase strength of the first busbar portion 26.

As illustrated in FIG. 1, the plurality of first connecting portions 26d are provided on, for example, the extension lines of the plurality of first electrode fingers 28. The disposition of the plurality of first connecting portions 26d is not limited to the above.

The first busbar portion 26 does not necessarily include the inner busbar 26b. In this case, the first busbar portion 26 does not include the plurality of first connecting portions 26d and the plurality of second connecting portions 26e. However, it is preferable that the first busbar portion 26 includes the inner busbar 26b. This can reduce or prevent an influence of the plurality of protruding electrodes 26c on the electrical characteristics of the acoustic wave device 10. These preferable configurations of the first busbar portion 26 are similarly preferable in the second busbar portion 27.

It is sufficient that the plurality of electrode fingers of the IDT electrode 11 includes at least one first electrode finger 28 and at least one second electrode finger 29. That is, the plurality of electrode fingers include only one pair of the first electrode finger 28 and the second electrode finger 29. In the present specification, in this case, even when the first electrode finger 28 and the second electrode finger 29 face each other in the electrode finger orthogonal direction, the first electrode finger 28 and the second electrode finger 29 are considered to be interdigitated with each other.

A dielectric film may be provided on the first main surface 14a of the piezoelectric layer 14 so as to cover the IDT electrode 11. Thus, the IDT electrode 11 is protected by the dielectric film, and thus the IDT electrode 11 is less likely to be damaged. As a material of the dielectric film, for example, silicon oxide, silicon nitride, silicon oxynitride, or the like can be used. The material of the dielectric film is not limited to the above. This configuration can also be applied to configurations of other example embodiments of the present invention.

In the first example embodiment, the IDT electrode 11 is provided on the first main surface 14a of the piezoelectric layer 14. However, it is sufficient that the IDT electrode 11 is provided on at least one of the first main surface 14a and the second main surface 14b of the piezoelectric layer 14. When the IDT electrode 11 is provided on the second main surface 14b, a portion of each protruding electrode 26c, a portion of the inner busbar 26b and the outer busbar 26a of the first busbar portion 26 are in contact with the support 13. A portion of each first connecting portion 26d and each second connecting portion 26e of the first busbar portion 26 are also in contact with the support 13. The same applies to the second busbar portion 27.

Even when the IDT electrode 11 is provided on the second main surface 14b, extension of a crack along each busbar portion can be reduced or prevented as in the first example embodiment. Thus, breakage of the plurality of electrode fingers can be reduced or prevented, and deterioration in the electrical characteristics of the acoustic wave device can be reduced or prevented.

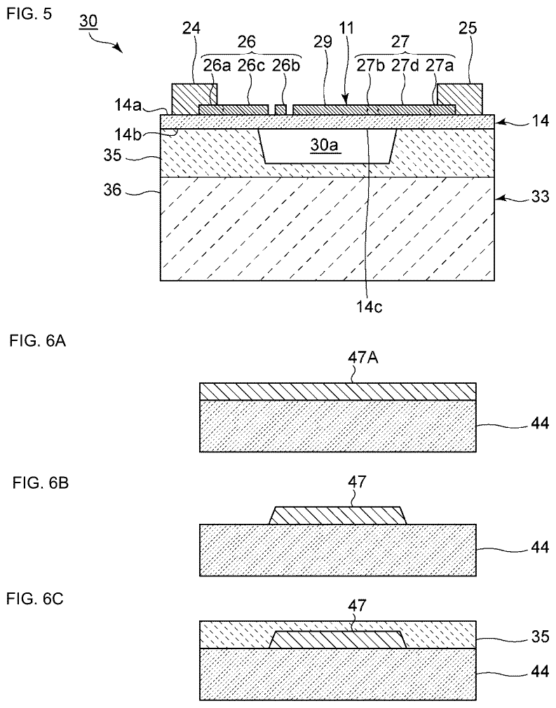

FIG. 5 is a schematic cross-sectional view of an acoustic wave device according to a second example embodiment of the present invention, taken along the electrode finger extending direction.

The present example embodiment is different from the first example embodiment in that a support 33 includes a support substrate 36 and the insulating layer 35, and a cavity portion 30a is provided in an insulating layer 35. Except for the above points, an acoustic wave device 30 of the present example embodiment has the same or similar configurations as those of the acoustic wave device 10 of the first example embodiment.

The insulating layer 35 is provided on the support substrate 36. The piezoelectric layer 14 is provided on the insulating layer 35. As a material of the insulating layer 35, an appropriate dielectric such as, for example, silicon oxide or tantalum oxide can be used.

As illustrated in FIG. 5, a concave portion is provided in the insulating layer 35. The piezoelectric layer 14 is provided on the insulating layer 35 so as to close the concave portion. Thus, a hollow portion is provided. This hollow portion is the cavity portion 30a. In the present example embodiment, the support 33 and the piezoelectric layer 14 are disposed such that a portion of the support 33 and a portion of the piezoelectric layer 14 face each other with the cavity portion 30a interposed therebetween. However, the concave portion in the support 33 may be provided in both of the insulating layer 35 and the support substrate 36. Alternatively, the concave portion provided only in the support substrate 36 may be closed by the insulating layer 35. The cavity portion 30a may be a through-hole provided in the support 33.

In the present example embodiment, the IDT electrode 11 is provided in the same or substantially the same manner as in the first example embodiment. Therefore, the first busbar portion 26 includes the plurality of protruding electrodes 26c, and the plurality of protruding electrodes 26c overlaps an outer peripheral edge of the cavity portion 30a in plan view. This makes it possible to move a portion where stress is concentrated from the region between the intersection region and the first busbar portion 26 toward the center of the membrane portion 14c, and to reduce the stress itself. In addition, the first busbar portion 26 includes the plurality of protruding electrodes 26c, and thus it is possible to disperse the stress. Thus, extension of a crack along the first busbar portion 26 can be reduced or prevented. Thus, breakage of the first electrode finger 28 illustrated with reference to FIG. 1 can be reduced or prevented, and deterioration in electrical characteristics of the acoustic wave device 30 can be reduced or prevented.

The second busbar portion 27 is also configured in the same or substantially the same manner as the first busbar portion 26. This can reduce or prevent extension of a crack along the second busbar portion 27. Thus, deterioration in the electrical characteristics of the acoustic wave device 30 can be more reliably reduced or prevented.

An example of a method for manufacturing the acoustic wave device 30 of the present example embodiment will be described below.

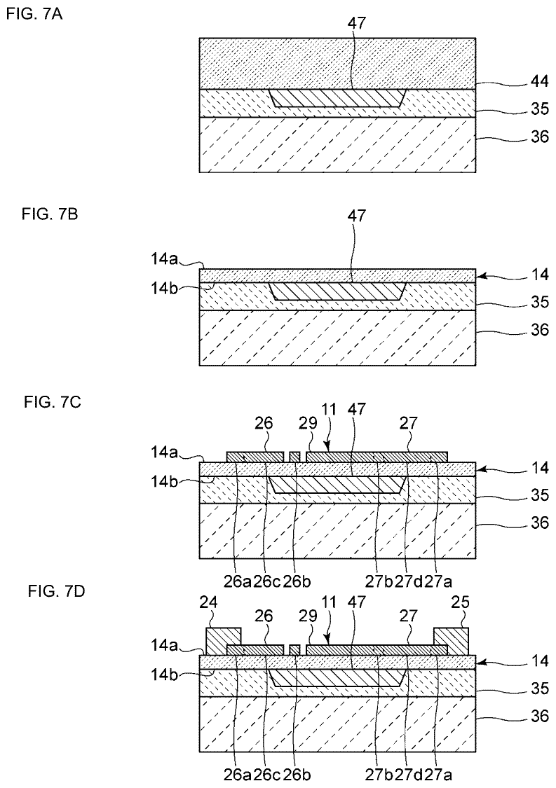

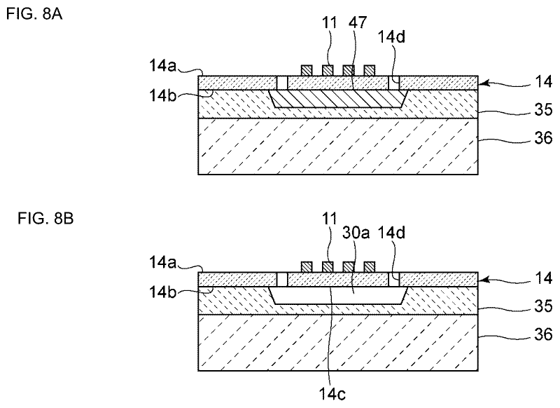

FIGS. 6A to 6C are schematic cross-sectional views illustrating a portion corresponding to the cross-section illustrated in FIG. 5, for explaining a sacrificial layer forming step and an insulating layer forming step in an example of the method for manufacturing the acoustic wave device according to the second example embodiment. FIGS. 7A to 7D are schematic cross-sectional views illustrating a portion corresponding to the cross-section illustrated in FIG. 5, for explaining a support substrate bonding step, a piezoelectric layer grinding step, an IDT electrode forming step and a wiring electrode forming step in the example of the method for manufacturing the acoustic wave device according to the second example embodiment. FIGS. 8A and 8B are schematic elevational cross-sectional views for explaining a through-hole forming step and a sacrificial layer removing step in the example of the method for manufacturing the acoustic wave device according to the second example embodiment.

As illustrated in FIG. 6A, a piezoelectric substrate 44 is prepared. The piezoelectric substrate 44 is included in the piezoelectric layer. Next, a sacrificial layer 47A is formed on the piezoelectric substrate 44. Next, the sacrificial layer 47A is appropriately patterned by performing, for example, etching, or the like. Thus, as illustrated in FIG. 6B, a sacrificial layer 47 is formed. As a material of the sacrificial layer 47, for example, ZnO, SiO₂, Cu or resin can be used.

Next, as illustrated in FIG. 6C, the insulating layer 35 is formed so as to cover the sacrificial layer 47. The insulating layer 35 can be formed by, for example, a sputtering method, a vacuum deposition method, or the like.

Next, as illustrated in FIG. 7A, the support substrate 36 is bonded to the insulating layer 35. For example, an insulating layer may be separately formed on the support substrate 36, and then the insulating layer and the insulating layer 35 covering the sacrificial layer 47 may be bonded to each other.

Next, a thickness of the piezoelectric substrate 44 is reduced by, for example, grinding or polishing a main surface side of the piezoelectric substrate 44 not provided with the insulating layer 35. For example, grinding, a chemical mechanical polishing (CMP) method, an ion slice method, etching, or the like can be used to adjust the thickness of the piezoelectric substrate 44. Thus, as illustrated in FIG. 7B, the piezoelectric layer 14 is obtained.

Next, as illustrated in FIG. 7C, the IDT electrode 11 is formed. The IDT electrode 11 can be formed by, for example, a sputtering method, a vacuum deposition method, or the like.

Next, as illustrated in FIG. 7D, the wiring electrode 24 is formed on top of the outer busbar 26a of the first busbar portion 26 and the piezoelectric layer 14. Similarly, the wiring electrode 25 is formed on top of the outer busbar 27a of the second busbar portion 27 and the piezoelectric layer 14. The wiring electrode 24 and the wiring electrode 25 can be formed by, for example, a sputtering method, a vacuum deposition method, or the like.

Next, as illustrated in FIG. 8A, the plurality of through-holes 14d are formed in the piezoelectric layer 14. To be more specific, the plurality of through-holes 14d are formed in the piezoelectric layer 14 so as to extend to the sacrificial layer 47. The through-hole 14d can be formed by, for example, a reactive ion etching (RIE) method or the like. Next, the sacrificial layer 47 is removed via the through-hole 14d. To be more specific, the sacrificial layer 47 in the concave portion in the insulating layer 35 is removed by, for example, making an etching solution flow in from the through-hole 14d. Thus, as illustrated in FIG. 8B, the cavity portion 30a is formed.

Thus, the acoustic wave device 30 illustrated in FIG. 5 is obtained. The above manufacturing method is merely an example, and the acoustic wave device 30 may be obtained by another method.

A thickness-shear mode will be described in detail below using an example of an IDT electrode in the related art. An “electrode” in an IDT electrode described below corresponds to the electrode finger. A support in the following example corresponds to the support substrate.

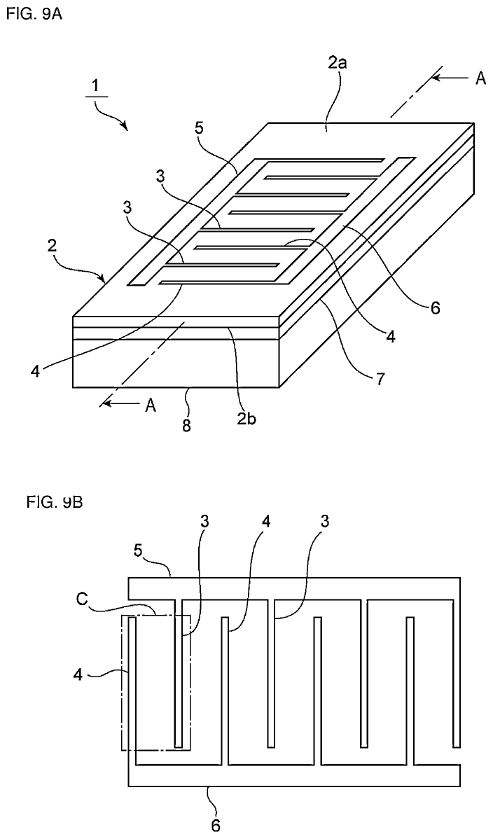

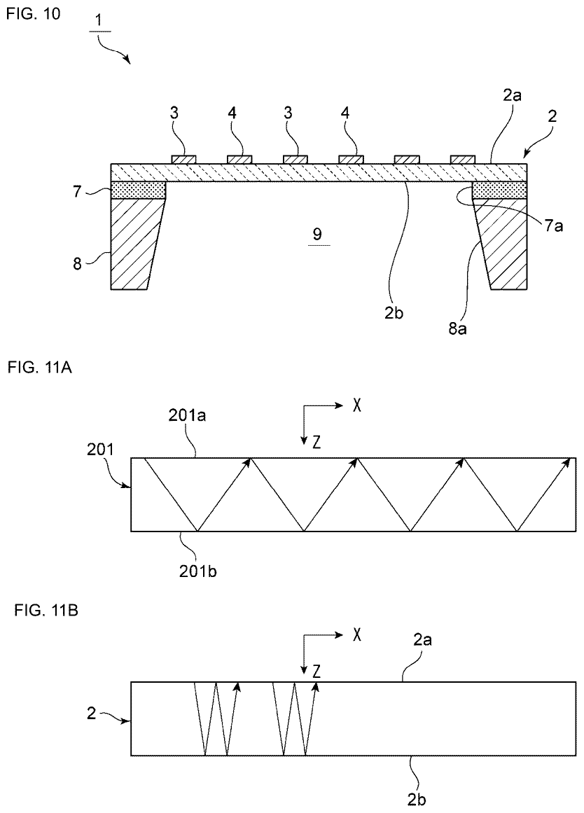

FIG. 9A is a schematic perspective view illustrating an appearance of an acoustic wave device in which a bulk wave in the thickness-shear mode is used, FIG. 9B is a plan view illustrating an electrode structure on a piezoelectric layer, and FIG. 10 is a cross-sectional view of a portion taken along a line A-A in FIG. 9A.

The acoustic wave device 1 includes a piezoelectric layer 2 made of, for example, LiNbO₃. The piezoelectric layer 2 may be made of, for example, LiTaO₃. A cut angle of LiNbO₃ or LiTaO₃ is, for example, Z-cut, but may be rotated Y-cut or X-cut. A thicknesses of the piezoelectric layer 2 is not particularly limited, but is, for example, preferably equal to or greater than about 40 nm and equal to or less than about 1000 nm, and more preferably equal to or greater than about 50 nm and equal to or less than about 1000 nm in order to effectively excite the thickness-shear mode. The piezoelectric layer 2 includes first and second main surfaces 2a and 2b facing each other. An electrode 3 and an electrode 4 are provided on the first main surface 2a. Here, the electrode 3 is an example of a “first electrode”, and the electrode 4 is an example of a “second electrode”. In FIGS. 9A and 9B, a plurality of the electrodes 3 includes a plurality of first electrode fingers connected to a first busbar portion 5. A plurality of the electrodes 4 include a plurality of second electrode fingers connected to a second busbar portion 6. The plurality of electrodes 3 and the plurality of electrodes 4 are interdigitated with each other. The electrode 3 and the electrode 4 each have a rectangular or substantially rectangular shape and have a length direction. The electrode 3 and the electrode 4 adjacent to each other face each other in a direction orthogonal or substantially orthogonal to the length direction. The length direction of the electrodes 3 and 4 and the direction orthogonal or substantially orthogonal to the length direction of the electrodes 3 and 4 are both directions intersecting a thickness direction of the piezoelectric layer 2. Thus, it can be said that the electrode 3 and the adjacent electrode 4 face each other in the direction intersecting the thickness direction of the piezoelectric layer 2. Further, the length direction of the electrodes 3 and 4 may be switched with a direction orthogonal or substantially orthogonal to the length direction of the electrodes 3 and 4 illustrated in FIGS. 9A and 9B. That is, in FIGS. 9A and 9B, the electrodes 3 and 4 may be extended in a direction in which the first busbar portion 5 and the second busbar portion 6 extend. In this case, the first busbar portion 5 and the second busbar portion 6 extend in a direction in which the electrodes 3 and 4 extend in FIGS. 9A and 9B. Then, a structure of a pair of the electrode 3 connected to one potential and the electrode 4 connected to another potential adjacent to each other is plurally provided in the direction orthogonal or substantially orthogonal to the length direction of the electrodes 3 and 4. The electrode 3 and the electrode 4 being adjacent to each other does not refer to a case where the electrode 3 and the electrode 4 are disposed so as to be in direct contact with each other, but refers to a case where the electrode 3 and the electrode 4 are disposed with an interval interposed therebetween. Further, when the electrode 3 and the electrode 4 are adjacent to each other, no electrode connected to a hot electrode or a ground electrode, including the other electrodes 3 and 4, is disposed between the electrode 3 and the electrode 4. The number of pairs is not necessarily an integer, and, for example, may be 1.5, 2.5, or the like. A center-to-center distance between the electrodes 3 and 4, that is, a pitch, is, for example, preferably in a range of equal to or greater than about 1 μm and equal to or less than about 10 μm. Further, widths of the electrodes 3 and 4, that is, dimensions of the electrodes 3 and 4 in a facing direction are, for example, preferably in a range of equal to or greater than about 50 nm and equal to or less than about 1000 nm, and more preferably in a range of equal to or greater than about 150 nm and equal to or less than about 1000 nm. The center-to-center distance between the electrodes 3 and 4 is a distance between a center of the dimension (width dimension) of the electrode 3 in the direction orthogonal or substantially orthogonal to the length direction of the electrode 3 and a center of the dimension (width dimension) of the electrode 4 in the direction orthogonal or substantially orthogonal to the length direction of the electrode 4.

In addition, in the acoustic wave device 1, since the Z-cut piezoelectric layer is used, the direction orthogonal or substantially orthogonal to the length direction of the electrodes 3 and 4 is a direction orthogonal or substantially orthogonal to a polarization direction of the piezoelectric layer 2. This is not the case when a piezoelectric material having a different cut angle is used for the piezoelectric layer 2. Here, “orthogonal” is not limited to a case of being strictly orthogonal, and may be substantially orthogonal (an angle between the direction orthogonal or substantially orthogonal to the length direction of the electrodes 3 and 4 and the polarization direction is, for example, within a range of about 90°±10°).

A support 8 is laminated on the piezoelectric layer 2 on a side of the second main surface 2b with an insulating layer 7 interposed therebetween. The insulating layer 7 and the support 8 each have a frame shape, and include through-holes 7a and 8a as illustrated in FIG. 10. Thus, a cavity portion 9 is provided. The cavity portion 9 is provided so as not to hinder a vibration of an excitation region C of the piezoelectric layer 2. Thus, the above support 8 is laminated on the second main surface 2b with the insulating layer 7 interposed therebetween at a position not overlapping a portion provided with at least a pair of the electrodes 3 and 4. The insulating layer 7 need not be provided. Thus, the support 8 can be directly or indirectly laminated on the second main surface 2b of the piezoelectric layer 2.

The insulating layer 7 is made of, for example, silicon oxide. However, other than silicon oxide, an appropriate insulating material such as, for example, silicon oxynitride or alumina can be used. The support 8 is made of, for example, Si. A plane orientation of a surface of Si on a side of the piezoelectric layer 2 may be, for example, (100), (110) or (111). Si of the support 8 is preferably high in resistance with a resistivity equal to or greater than about 4 kΩcm, for example. However, the support 8 may also be made by using an appropriate insulating material or semiconductor material.

As the material of the support 8, for example, a piezoelectric material such as aluminum oxide, lithium tantalate, lithium niobate, or quartz, various ceramics such as alumina, magnesia, sapphire, silicon nitride, aluminum nitride, silicon carbide, zirconia, cordierite, mullite, steatite, or forsterite, a dielectric material such as diamond or glass, or a semiconductor such as gallium nitride can be used.

The plurality of electrodes 3 and 4 and the first and second busbar portions 5 and 6 described above are made of appropriate metal or alloy such as, for example, Al or an AlCu alloy. In the acoustic wave device 1, the electrodes 3 and 4 and the first and second busbar portions 5 and 6 each have, for example, a structure in which an Al film is laminated on a Ti film. An adhesion layer other than the Ti film may be used.

In driving, an AC voltage is applied to a gap between the plurality of electrodes 3 and the plurality of electrodes 4. More specifically, an AC voltage is applied to a gap between the first busbar portion 5 and the second busbar portion 6. Thus, it is possible to obtain resonance characteristics by using a bulk wave in a thickness-shear mode excited in the piezoelectric layer 2. In addition, for example, in the acoustic wave device 1, d/p is set to be equal to or less than about 0.5, where d is the thickness of the piezoelectric layer 2 and p is the center-to-center distance between any adjacent electrodes 3 and 4 of the plurality of pairs of electrodes 3 and 4. Thus, the bulk wave in the thickness-shear mode described above is effectively excited, and good resonance characteristics can be obtained. More preferably, for example, d/p is equal to or less than about 0.24, and in this case, even better resonance characteristics can be obtained.

Since the acoustic wave device 1 has the above configuration, even when the number of pairs of the electrodes 3 and 4 is reduced in order to attempt miniaturization, a Q value is unlikely to be reduced. This is because a propagation loss is small even when the number of electrode fingers in reflectors on both sides is reduced. Further, the number of electrode fingers described above can be reduced because the bulk wave in the thickness-shear mode is used. A difference between a Lamb wave used in the acoustic wave device and the bulk wave in the thickness-shear mode will be described with reference to FIGS. 11A and 11B.

FIG. 11A is a schematic elevational cross-sectional view for explaining a Lamb wave propagating through a piezoelectric film of an acoustic wave device as described in Laid-open Disclosure Public Patent Bulletin Japanese Unexamined Patent Application Publication No. 2012-257019. Here, the wave propagates in a piezoelectric film 201 as indicated by arrows. In the piezoelectric film 201, a first main surface 201a and a second main surface 201b face each other, and a thickness direction in which the first main surface 201a and the second main surface 201b are connected is a Z direction. An X direction is a direction in which electrode fingers of an IDT electrode are arranged. As illustrated in FIG. 11A, the Lamb wave propagates in the X direction as illustrated in the drawing. Although the piezoelectric film 201 vibrates as a whole because the wave is a plate wave, the wave propagates in the X direction, and thus reflectors are disposed on both sides to obtain resonance characteristics. Accordingly, a propagation loss of the wave occurs, and thus when miniaturization is attempted, that is, when the number of pairs of electrode fingers is reduced, a Q value is reduced.

On the other hand, as illustrated in FIG. 11B, in the acoustic wave device 1, vibration movement occurs in a thickness-shear direction, and thus a wave propagates substantially in the direction in which the first main surface 2a and the second main surface 2b of the piezoelectric layer 2 are connected, that is, in the Z direction, and resonates. That is, an X direction component of the wave is significantly smaller than a Z direction component. Then, since resonance characteristics are obtained by the propagation of the wave in the Z direction, a propagation loss is less likely to be generated even when the number of electrode fingers of the reflector is reduced. Further, even when the number of electrode pairs of the electrodes 3 and 4 is reduced to promote miniaturization, a Q value is less likely to be reduced.

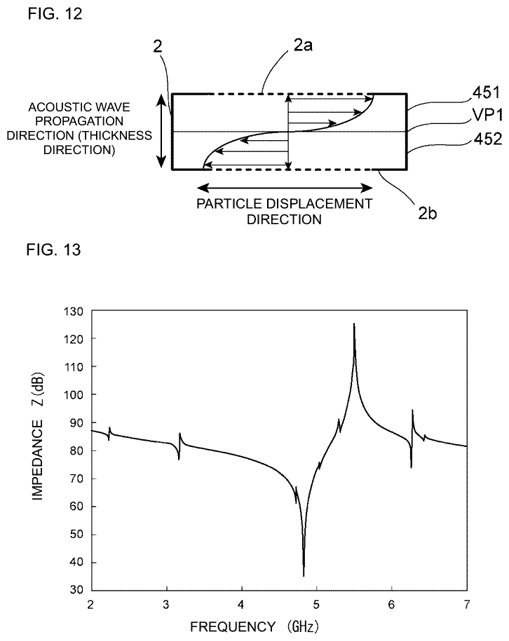

As illustrated in FIG. 12, an amplitude direction of the bulk wave in the thickness-shear mode is reversed between a first region 451 included in the excitation region C of the piezoelectric layer 2 and a second region 452 included in the excitation region C. FIG. 12 schematically illustrates a bulk wave when voltage is applied to a gap between the electrode 3 and the electrode 4 such that the electrode 4 is higher in potential than the electrode 3. The first region 451 is a region of the excitation region C between the first main surface 2a and a virtual plane VP1 that is orthogonal to the thickness direction of the piezoelectric layer 2 and bisects the piezoelectric layer 2. The second region 452 is a region of the excitation region C between the virtual plane VP1 and the second main surface 2b.

As described above, in the acoustic wave device 1, at least one pair of electrodes including the electrode 3 and the electrode 4 are disposed, but since the acoustic wave device 1 does not propagate a wave in the X direction, the number of pairs of electrodes including the electrodes 3 and 4 does not need to be plural. That is, it is sufficient that at least one pair of electrodes are provided.

For example, the electrode 3 is an electrode connected to a hot potential, and the electrode 4 is an electrode connected to the ground potential. However, the electrode 3 may be connected to the ground potential, and the electrode 4 may be connected to the hot potential. In the acoustic wave device 1, at least one pair of electrodes are each the electrode connected to the hot potential or the electrode connected to the ground potential, as described above, and no floating electrode is provided.

FIG. 13 is a graph showing resonance characteristics of the acoustic wave device illustrated in FIG. 10. Design parameters of the acoustic wave device 1 with which the resonance characteristics were obtained are as follows.
Piezoelectric layer 2: LiNbO₃ of Euler angles (0°, 0°, 90°), the thickness=about 400 nm.

When viewed in the direction orthogonal or substantially orthogonal to the length direction of the electrodes 3 and 4, a length of the region where the electrodes 3 and 4 overlap, that is, the excitation region C, was about 40 μm, the number of pairs electrodes including the electrodes 3 and 4 was 21, the center-to-center distance between the electrodes was about 3 μm, the widths of the electrodes 3 and 4 were about 500 nm, and d/p was about 0.133.
Insulating layer 7: a silicon oxide film having a thickness of about 1 μm.
Support 8: Si.

Note that the length of the excitation region C is a dimension of the excitation region C along the length direction of the electrodes 3 and 4.

In the acoustic wave device 1, the center-to-center distances between the electrodes of the electrode pairs including the electrodes 3 and 4 are set to be equal or substantially equal for all the plurality of pairs. That is, the electrodes 3 and the electrodes 4 were disposed at an equal pitch.

As is clear from FIG. 13, although no reflector is provided, good resonance characteristics with a fractional bandwidth of about 12.5% are obtained.

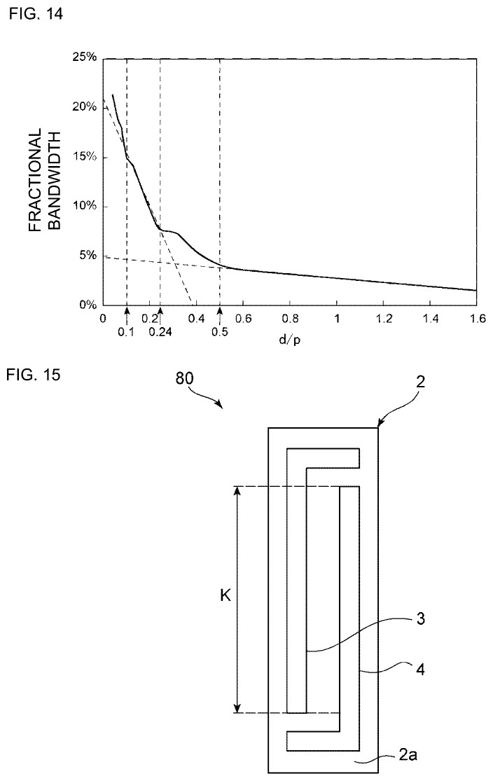

As described above, for example, in the acoustic wave device 1, d/p is equal to or less than about 0.5, and more preferably equal to or less than about 0.24, where d is the above thickness of the piezoelectric layer 2 and p is the center-to-center distance between the electrode 3 and the electrode 4. This will be described with reference to FIG. 14.

A plurality of acoustic wave devices were obtained in the same or substantially the same manner as the acoustic wave device having the resonance characteristics shown in FIG. 13, except that d/p was changed. FIG. 14 is a graph showing a relationship between d/p and fractional bandwidth of the acoustic wave device as a resonator.

As is clear from FIG. 14, when d/p>about 0.5, the fractional bandwidth is less than about 5% even when d/p is adjusted. On the other hand, when d/p≤about 0.5, the fractional bandwidth can be set to be equal to or greater than about 5% by changing d/p within the range, and thus, a resonator having a high coupling coefficient can be configured. Further, when d/p is equal to or less than about 0.24, the fractional bandwidth can be increased to be equal to or greater than about 7%. In addition, when d/p is adjusted within this range, a resonator having a further wider fractional bandwidth can be obtained, and a resonator having a further higher coupling coefficient can be achieved. Thus, it is understood that a resonator having a high coupling coefficient in which the bulk wave in the thickness-shear mode described above is used can be configured by, for example, setting d/p to be equal to or less than about 0.5.

FIG. 15 is a plan view of an acoustic wave device in which the bulk wave in the thickness-shear mode is used. In an acoustic wave device 80, a pair of electrodes including the electrodes 3 and 4 are provided on the first main surface 2a of the piezoelectric layer 2. In FIG. 15, K is an intersection width. As described above, in the acoustic wave device of the present invention, the number of pairs of electrodes may be one. Even in this case, for example, as long as d/p described above is equal to or less than about 0.5, the bulk wave in the thickness-shear mode can be effectively excited.

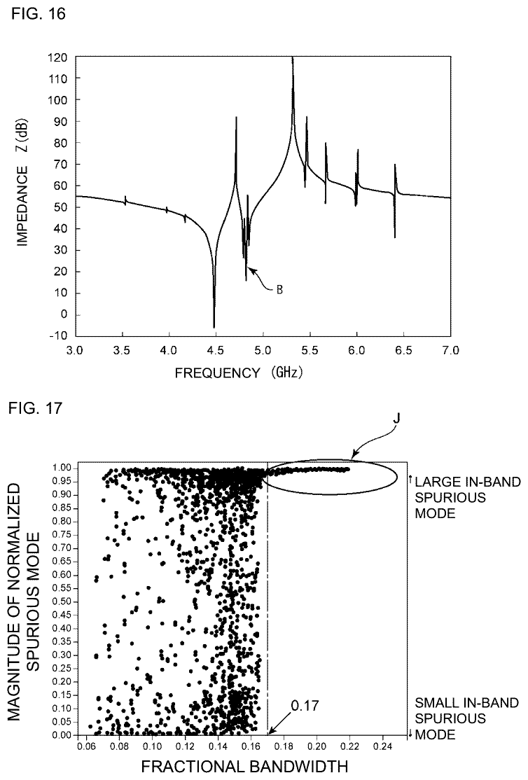

In the acoustic wave device 1, preferably, in a plurality of the electrodes 3 and 4, a metallization ratio MR of any adjacent electrodes 3 and 4 with respect to the excitation region C, which is a region where the adjacent electrodes 3 and 4 overlap each other when viewed in a facing direction, satisfies MR about 1.75 (d/p)+0.075, for example. In this case, a spurious mode can be effectively reduced. This will be described with reference to FIG. 16 and FIG. 17. FIG. 16 is a reference diagram showing an example of resonance characteristics of the above acoustic wave device 1. A spurious mode indicated by an arrow B appears between a resonant frequency and an anti-resonant frequency. d/p=0.08 and Euler angles of LiNbO₃ were (0°, 0°, 90°). Further, the above metallization ratio MR was set to about 0.35.

The metallization ratio MR will be described with reference to FIG. 9B. In an electrode structure of FIG. 9B, when attention is paid to a pair of the electrodes 3 and 4, it is assumed that only the pair of electrodes 3 and 4 are provided. In this case, a portion surrounded by a one-dot chain line is the excitation region C. The excitation region C is a region of the electrode 3 overlapping the electrode 4, a region of the electrode 4 overlapping the electrode 3, and a region between the electrode 3 and the electrode 4 where the electrode 3 and the electrode 4 overlap each other, when the electrode 3 and the electrode 4 are viewed in the direction orthogonal to the length direction of the electrodes 3 and 4, that is, in the facing direction. Then, an area of the electrodes 3 and 4 in the excitation region C with respect to an area of the excitation region C results in the metallization ratio MR. That is, the metallization ratio MR is a ratio of an area of a metallization portion to the area of the excitation region C.

When a plurality of pairs of electrodes are provided, it is sufficient that a ratio of metallization portions included in entire excitation regions to a total area of the excitation regions is defined as MR.

FIG. 17 is a graph showing a relationship between fractional bandwidth and phase rotation amount of impedance of a spurious mode normalized by about 180 degrees as a magnitude of the spurious mode when a large number of acoustic wave resonators are configured in accordance with the example embodiment of the acoustic wave device 1. The fractional bandwidth was adjusted by changing the film thickness of the piezoelectric layer and the dimensions of the electrodes in various ways. Further, FIG. 17 shows results when the piezoelectric layer made of Z-cut LiNbO₃ was used, but a similar tendency is obtained when a piezoelectric layer having another cut angle is used.

In a region surrounded by an ellipse J in FIG. 17, the spurious mode is as large as about 1.0. As is clear from FIG. 17, when the fractional bandwidth exceeds about 0.17, that is, exceeds about 17%, a large spurious mode having a spurious level of equal to or greater than about 1 appears in a pass band even when the parameters defining the fractional bandwidth are changed. That is, as in the resonance characteristics shown in FIG. 16, the large spurious mode indicated by the arrow B appears in the band. Thus, the fractional bandwidth is, for example, preferably equal to or less than about 17%. In this case, the spurious mode can be reduced by adjusting the film thickness of the piezoelectric layer 2 and the dimensions of the electrodes 3 and 4, for example.

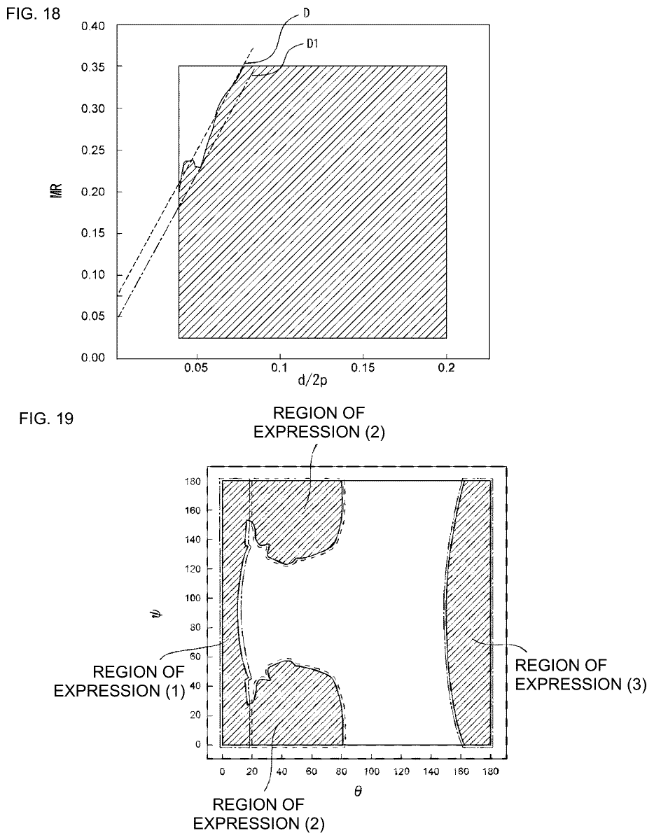

FIG. 18 is a graph showing a relationship between d/2p, the metallization ratio MR and fractional bandwidth. In the above acoustic wave device, various acoustic wave devices having different d/2p and MR were configured, and the fractional bandwidth was measured. A hatched portion on a right side of a broken line D in FIG. 18 is a region where the fractional bandwidth is equal to or less than about 17%. A boundary between the hatched region and an unhatched region is represented by, for example, MR=about 3.5 (d/2p)+0.075. That is, MR=about 1.75 (d/p)+0.075. Therefore, for example, preferably, MR about 1.75 (d/p)+0.075. In this case, the fractional bandwidth is easily set to be equal to or less than about 17%. A region on a right side of MR=about 3.5 (d/2p)+0.05 indicated by a one-dot chain line D1 in FIG. 18 is more preferable. That is, for example, as long as MR about 1.75 (d/p)+0.05, the fractional bandwidth can be reliably set to be equal to or less than about 17%.

FIG. 19 is a graph showing a map of fractional bandwidth with respect to Euler angles (0°, θ, ψ) of LiNbO₃ when d/p is made to approach 0 without limit. Hatched portions in FIG. 19 are regions where the fractional bandwidth of at least equal to or greater than 5% is obtained, and ranges of the regions are approximated to ranges represented by Expression (1), Expression (2), or Expression (3) described below.

$$( 0 ° \pm 10 ° , 0 ° to 20 ° , arbitrary ψ ) \qquad Expression ( 1 )$$

$$( 0 ° \pm 10 ° , 20 ° to 80 ° , 0 ° to 60 {° ( 1 - {( θ - 50 )}^{2} / 900 )}^{1 / 2} ) or \\ ( 0 ° \pm 10 ° , 20 ° to 90 ° , \\ [ 180 ° - 60 {° ( 1 - {( θ - 50 )}^{2} / 900 )}^{1 / 2} ] to 180 ° ) \qquad Expression ( 2 )$$

$$( 0 ° \pm 10 ° , [ 180 ° - 30 {° ( 1 - {( ψ - 90 )}^{2} / 8100 )}^{1 / 2} ] to 180 ° , \\ arbitrary ψ ) \qquad Expression ( 3 )$$

Thus, the fractional bandwidth can be sufficiently widened in the case of the Euler angle range represented by the above Expression (1), Expression (2) or Expression (3), which is preferable. The same applies to the case where the piezoelectric layer 2 is a lithium tantalate layer.

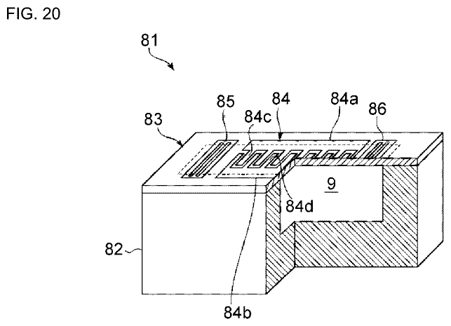

FIG. 20 is a partially cutaway perspective view for explaining an acoustic wave device in which a Lamb wave is used.

An acoustic wave device 81 includes a support substrate 82. The support substrate 82 is provided with a concave portion opened on an upper surface thereof. A piezoelectric layer 83 is laminated on the support substrate 82. Thus, the cavity portion 9 is provided. An IDT electrode 84 is provided on the piezoelectric layer 83 above the cavity portion 9. Reflectors 85 and 86 are provided on both sides of the IDT electrode 84 in an acoustic wave propagation direction. In FIG. 20, an outer peripheral edge of the cavity portion 9 is indicated by a broken line. Here, the IDT electrode 84 includes first and second busbar portions 84a and 84b, a plurality of first electrode fingers 84c and a plurality of second electrode fingers 84d. The plurality of first electrode fingers 84c are connected to the first busbar portion 84a. The plurality of second electrode fingers 84d are connected to the second busbar portion 84b. The plurality of first electrode fingers 84c and the plurality of second electrode fingers 84d are interdigitated with each other.

In the acoustic wave device 81, an alternating electric field is applied to the IDT electrode 84 on the cavity portion 9, and thus a Lamb wave as a plate wave is excited. Then, since the reflectors 85 and 86 are provided on both the sides, resonance characteristics by the above Lamb wave can be obtained.

As described above, an acoustic wave device according to an example embodiment of the present invention may be one in which a plate wave is used. In the example illustrated in FIG. 20, the IDT electrode 84, the reflectors 85 and 86 are provided on a main surface corresponding to the first main surface 14a of the piezoelectric layer 14 illustrated in FIG. 2 and the like. When the acoustic wave device is one in which a plate wave is used, it is sufficient that the IDT electrode of the present invention, and the reflectors 85 and 86 illustrated in FIG. 20 are provided on the first main surface 14a or the second main surface 14b of the piezoelectric layer 14 in the acoustic wave device of the first or second example embodiment.

In the acoustic wave device of the first example embodiment or the second example embodiment in which a bulk wave in a thickness-shear mode is used, for example, d/p is preferably equal to or less than about 0.5, and more preferably equal to or less than about 0.24, as described above. This makes it possible to obtain even better resonance characteristics. Furthermore, for example, in the excitation region of the acoustic wave device of the first example embodiment or the second example embodiment in which the bulk wave in the thickness-shear mode is used, as described above, MR about 1.75 (d/p)+0.075 is preferably satisfied. In this case, a spurious mode can be reduced or prevented more reliably.

The piezoelectric layer in the acoustic wave device of the first example embodiment or the second example embodiment in which the bulk wave in the thickness-shear mode is used is, for example, preferably a lithium niobate layer or a lithium tantalate layer. In addition, the Euler angles (φ, θ, ψ) of lithium niobate or lithium tantalate constituting the piezoelectric layer are preferably in the range of Expression (1), Expression (2) or Expression (3) described above. In this case, the fractional bandwidth can be sufficiently widened.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device, comprising:
a support including a support substrate;
a piezoelectric layer on a side of the support and including a first main surface and a second main surface facing each other; and
an interdigital transducer (IDT) electrode on a side of at least one of the first main surface and the second main surface of the piezoelectric layer; wherein
the IDT electrode includes a first busbar portion and a second busbar portion facing each other, and a plurality of electrode fingers including one or more first electrode fingers including one ends connected to the first busbar portion and one or more second electrode fingers including one ends connected to the second busbar portion, and the first electrode fingers and the second electrode fingers are interdigitated with each other;
a region where the first electrode fingers and the second electrode fingers adjacent to each other overlap each other when viewed from a direction orthogonal or substantially orthogonal to a direction in which the first electrode fingers and the second electrode fingers extend is an intersection region;
the support includes a cavity portion overlapping the intersection region in plan view; and
at least one of the first busbar portion and the second busbar portion includes an outer busbar not overlapping the cavity portion in plan view, and one or more protruding electrodes extending from the outer busbar toward the intersection region and facing an electrode finger of the plurality of electrode fingers that is not connected to the outer busbar, and the one or more protruding electrodes overlap an outer peripheral edge of the cavity portion in plan view.

2. The acoustic wave device according to claim 1, wherein both of the first busbar portion and the second busbar portion includes the one or more protruding electrodes.

3. The acoustic wave device according to claim 1, wherein
the busbar portion including the one or more protruding electrodes, of the first busbar portion and the second busbar portion, further includes an inner busbar between the intersection region and the one or more protruding electrodes; and
the electrode fingers connected to the busbar portion including the inner busbar includes a connecting portion connecting the inner busbar and the outer busbar to each other.

4. The acoustic wave device according to claim 3, wherein
the connecting portion includes a first connecting portion;
the inner busbar extends to a portion not overlapping the cavity portion in plan view; and
the outer busbar includes at least one second connecting portion connecting the inner busbar and the outer busbar to each other.

5. The acoustic wave device according to claim 1, wherein
the piezoelectric layer includes lithium niobate or lithium tantalate.

6. The acoustic wave device according to claim 1, wherein
the acoustic wave device is structured to generate a bulk wave in a thickness-shear mode.

7. The acoustic wave device according to claim 1, wherein
d/p is equal to or less than about 0.5 where d is a thickness of the piezoelectric layer and p is a center-to-center distance between the electrode fingers adjacent to each other.

8. The acoustic wave device according to claim 7, wherein
d/p is equal to or less than about 0.24.

9. The acoustic wave device according to claim 1, wherein
the intersection region includes a plurality of excitation regions respectively located between centers of the electrode fingers adjacent to each other; and
MR about 1.75(d/p)+0.075 is satisfied, where MR is a metallization ratio of the plurality of electrode fingers to the excitation regions.

10. The acoustic wave device according to claim 1, wherein
the piezoelectric layer includes lithium niobate or lithium tantalate; and
Euler angles (φ, θ, ψ) of lithium niobate or lithium tantalate constituting the piezoelectric layer are in a range of Expression (1), Expression (2), or Expression (3):
$$( 0 ° \pm 10 ° , 0 ° to 20 ° , arbitrary ψ ) ; \qquad Expression ( 1 )$$
$$( 0 ° \pm 10 ° , 20 ° to 90 ° , 0 ° to 60 {° ( 1 - {( θ - 50 )}^{2} / 900 )}^{1 / 2} ) or \\ ( 0 ° \pm 10 ° , 20 ° to 80 ° , \\ [ 180 ° - 60 {° ( 1 - {( θ - 50 )}^{2} / 900 )}^{1 / 2} ] to 180 ° ) ; and \qquad Expression ( 2 )$$
$$( 0 ° \pm 10 ° , [ 180 ° - 30 {° ( 1 - {( ψ - 90 )}^{2} / 8100 )}^{1 / 2} ] to 180 ° , \\ arbitrary ψ ) . \qquad Expression ( 3 )$$

11. The acoustic wave device according to claim 1, wherein the acoustic wave device is structured to generate a plate wave.

12. The acoustic wave device according to claim 1, wherein a dielectric film is provided on the first main surface of the piezoelectric layer and covers the IDT electrode.

13. The acoustic wave device according to claim 12, wherein the dielectric film includes silicon oxide, silicon nitride, or silicon oxynitride.

14. The acoustic wave device according to claim 1, wherein an insulating layer is provided on the support substrate.

15. The acoustic wave device according to claim 14, wherein the insulating layer includes silicon oxide or tantalum oxide.

16. The acoustic wave device according to claim 1, wherein a thickness of the piezoelectric layer is equal to or greater than about 40 nm and equal to or less than about 1000 nm.

17. The acoustic wave device according to claim 1, wherein a thickness of the piezoelectric layer is equal to or greater than about 50 nm and equal to or less than about 1000 nm.

18. The acoustic wave device according to claim 1, wherein a dimension of each of the plurality of electrode fingers in a facing direction is in a range of equal to or greater than about 50 nm and equal to or less than about 1000 nm, and more preferably in a range of equal to or greater than about 150 nm and equal to or less than about 1000 nm.

19. The acoustic wave device according to claim 1, wherein a dimension of each of the plurality of electrode fingers in a facing direction is in a range of equal to or greater than about 150 nm and equal to or less than about 1000 nm.
